(19) United States
(12) Patent Application Publication
(10) Pub. No.: US 2025/0364760 A1
(43) Pub. Date: Nov. 27, 2025

(54) FIRST ELECTRICAL CONNECTOR AND CONNECTOR ASSEMBLY WITH IMPROVED SHIELDING FEATURES

(71) Applicant: DONGGUAN LUXSHARE TECHNOLOGIES CO., LTD, Dongguan City (CN)

(72) Inventors: Bin HUANG, Dongguan City (CN); Chuanqi GONG, Dongguan City (CN); Kunlin YAO, Dongguan City (CN); Hongji CHEN, Dongguan City (CN)

(73) Assignee: DONGGUAN LUXSHARE TECHNOLOGIES CO., LTD, Dongguan City (CN)

(21) Appl. No.: 18/933,580

(22) Filed: Oct. 31, 2024

(30) Foreign Application Priority Data
May 27, 2024 (CN) 202410666592.4

(51) Int. Cl. H01R 13/6594; H01R 12/71; H01R 12/75

(52) U.S. Cl. CPC H01R 13/6594; H01R 12/716; H01R 12/75

(57) ABSTRACT

A first electrical connector is configured to be mounted to a circuit board along a first direction. The first electrical connector includes a conductive housing and a number of conductive terminals. The conductive housing defines a first receiving slot configured to at least partially receive a first mating connector along the first direction. The first direction is perpendicular to the circuit board. The conductive terminals are at least partially disposed in the conductive housing but are not in contact with the conductive housing. A connector assembly having the first electrical connector is also disclosed.

### CROSS-REFERENCE TO RELATED APPLICATION

This patent application claims priority of a Chinese Patent Application No. 202410666592.4, filed on May 27, 2024 and titled “FIRST ELECTRICAL CONNECTOR AND CONNECTOR ASSEMBLY”, the entire content of which is incorporated herein by reference.

### TECHNICAL FIELD

The present disclosure relates to a first electrical connector and a connector assembly, which belong to the technical field of connectors.

### BACKGROUND

Connector assemblies in the related art include electrical connectors, wherein the electrical connector includes an insulating body, a plurality of conductive terminals mounted to the insulating body and a metal shell fixed to the insulating body. The plurality of conductive terminals include a plurality of signal terminals. However, as the requirements for signal transmission quality of electrical connectors continue to increase, there is still room for improvement in electrical connectors and electrical connector assemblies in related technologies.

### SUMMARY

An object of the present disclosure is to provide a first electrical connector and connector assembly with improved shielding features.

In order to achieve the above object, the present disclosure adopts the following technical solution: a first electrical connector, configured to be mounted to a circuit board along a first direction, the first electrical connector including: a conductive housing, the conductive housing defining a first receiving slot, the first receiving slot extending along the first direction and being configured to at least partially receive a first mating connector along the first direction; the first direction being perpendicular to the circuit board; and a plurality of conductive terminals, the plurality of conductive terminals being at least partially disposed in the conductive housing. each conductive terminal including a contact arm, the contact arm including a contact portion which at least partially extends into the first receiving slot and is configured to be in electrical contact with the first mating connector; the plurality of conductive terminals being not in contact with the conductive housing.

In order to achieve the above object, the present disclosure adopts the following technical solution: a connector assembly, including: a first electrical connector, configured to be mounted to a circuit board along a first direction, the first electrical connector including: a conductive housing, the conductive housing defining a first receiving slot, the first receiving slot extending along the first direction and being configured to at least partially receive a first mating connector along the first direction; the first direction being perpendicular to the circuit board; and a plurality of conductive terminals, the plurality of conductive terminals being at least partially disposed in the conductive housing. each conductive terminal including a contact arm, the contact arm including a contact portion which at least partially extends into the first receiving slot and is configured to be in electrical contact with the first mating connector; the plurality of conductive terminals being not in contact with the conductive housing; and a shielding cage assembly, the shielding cage assembly being configured to be mounted to the circuit board along the first direction; the shielding cage assembly defining a first receiving cavity communicating with the first receiving slot along the first direction; the first receiving cavity and the first receiving slot being configured to jointly at least partially receive the first mating connector.

In order to achieve the above object, the present disclosure adopts the following technical solution: a connector assembly, including: a first electrical connector, configured to be mounted to a circuit board along a first direction, the first electrical connector including: a conductive housing, the conductive housing defining a first receiving slot, the first receiving slot extending along the first direction and being configured to at least partially receive a first mating connector along the first direction; the first direction being perpendicular to the circuit board; and a plurality of conductive terminals, the plurality of conductive terminals being at least partially disposed in the conductive housing. each conductive terminal including a contact arm, the contact arm including a contact portion which at least partially extends into the first receiving slot and is configured to be in electrical contact with the first mating connector; the plurality of conductive terminals being not in contact with the conductive housing; a second electrical connector, the second electrical connector defining a second receiving slot extending along the first direction; and a shielding cage assembly, the shielding cage assembly being configured to be mounted to the circuit board, the shielding cage assembly including a first metal shell, a second metal shell buckled together with the first metal shell, and an intermediate metal shell fixed to the first metal shell; the intermediate metal shell dividing the shielding cage assembly into a first receiving cavity and a second receiving cavity which are disposed on two sides of the intermediate metal shell, respectively; wherein the first receiving cavity and the first receiving slot are in communication along the first direction and are configured to jointly at least partially receive a first mating connector; and wherein the second receiving cavity is in communication with the second receiving slot along the first direction; the second receiving cavity and the second receiving slot are configured to jointly at least partially receive a second mating connector.

Compared with the prior art, the first electrical connector of the present disclosure includes the conductive housing. The plurality of conductive terminals are at least partially disposed in the conductive housing but are not in contact with the conductive housing. By providing the conductive housing instead of the insulating body in the related technology, the quality of signal transmission is improved. Besides, the first electrical connector is configured to be mounted to the circuit board along the first direction perpendicular to the circuit board. The first electrical connector of the present disclosure provides another installation method relative to the circuit board, which is beneficial to saving the area occupied by the first electrical connector on the circuit board. In addition, the connector assembly of the present disclosure includes the shielding cage assembly configured to be mounted to the circuit board along the first direction. The shielding cage assembly includes the first receiving cavity. The first receiving cavity is in communication with the first receiving slot along the first direction. The first receiving cavity and the first receiving slot are configured to at least partially receive the first mating connector. The connector assembly of the present disclosure improves the shielding effect on the conductive terminals and improves the quality of signal transmission.

### BRIEF DESCRIPTION OF DRAWINGS

FIG. 1 is a schematic perspective view of a connector assembly in accordance with an embodiment of the present disclosure;

FIG. 2 is a perspective view of FIG. 1 from another angle;

FIG. 3 is a partially exploded perspective view of FIG. 1, in which a first mating connector, a second mating connector and a circuit board are separated;

FIG. 4 is a partially exploded perspective view of FIG. 3 from another angle;

FIG. 5 is a front view of FIG. 3;

FIG. 6 is a partially exploded perspective view of FIG. 3 with the first mating connector, the second mating connector and the circuit board removed;

FIG. 7 is a partially exploded perspective view of FIG. 6 from another angle;

FIG. 8 is a schematic perspective view of the first electrical connector and the second electrical connector of the present disclosure when they are mounted to the circuit board;

FIG. 9 is a partially exploded perspective view of FIG. 8;

FIG. 10 is a partially exploded perspective view of FIG. 9 from another angle;

FIG. 11 is a partially exploded perspective view of the first electrical connector in FIG. 9, in which a first module and a second module are separated from each other;

FIG. 12 is a partially exploded perspective view of FIG. 11 from another angle;

FIG. 13 is a partial enlarged view of circled portion C in FIG. 11;

FIG. 14 is a partial enlarged view of circled portion D in FIG. 12;

FIG. 15 is an exploded perspective view of the first module in FIG. 11;

FIG. 16 is an exploded perspective view of FIG. 15 from another angle;

FIG. 17 is an exploded perspective view of FIG. 15 from yet another angle;

FIG. 18 is an exploded perspective view of the second module in FIG. 11;

FIG. 19 is an exploded perspective view of FIG. 18 from another angle;

FIG. 20 is an exploded perspective view of FIG. 18 from yet another angle;

FIG. 21 is a schematic cross-sectional view taken along line B-B in FIG. 1; and

FIG. 22 is a partial enlarged view of frame portion E in FIG. 21.

### DETAILED DESCRIPTION

Exemplary embodiments will be described in detail here, examples of which are shown in drawings. When referring to the drawings below, unless otherwise indicated, same numerals in different drawings represent the same or similar elements. The examples described in the following exemplary embodiments do not represent all embodiments consistent with this application. Rather, they are merely examples of devices and methods consistent with some aspects of the application as detailed in the appended claims.

The terminology used in this application is only for the purpose of describing particular embodiments, and is not intended to limit this application. The singular forms “a”, “said”, and “the” used in this application and the appended claims are also intended to include plural forms unless the context clearly indicates other meanings.

It should be understood that the terms “first”, “second” and similar words used in the specification and claims of this application do not represent any order, quantity or importance, but are only used to distinguish different components. Similarly, “an” or “a” and other similar words do not mean a quantity limit, but mean that there is at least one; “multiple” or “a plurality of” means two or more than two. Unless otherwise noted, “front”, “rear”, “lower” and/or “upper” and similar words are for ease of description only and are not limited to one location or one spatial orientation. Similar words such as “include” or “comprise” mean that elements or objects appear before “include” or “comprise” cover elements or objects listed after “include” or “comprise” and their equivalents, and do not exclude other elements or objects. The term “a plurality of” mentioned in the present disclosure includes two or more.

Hereinafter, some embodiments of the present disclosure will be described in detail with reference to the accompanying drawings. In the case of no conflict, the following embodiments and features in the embodiments can be combined with each other.

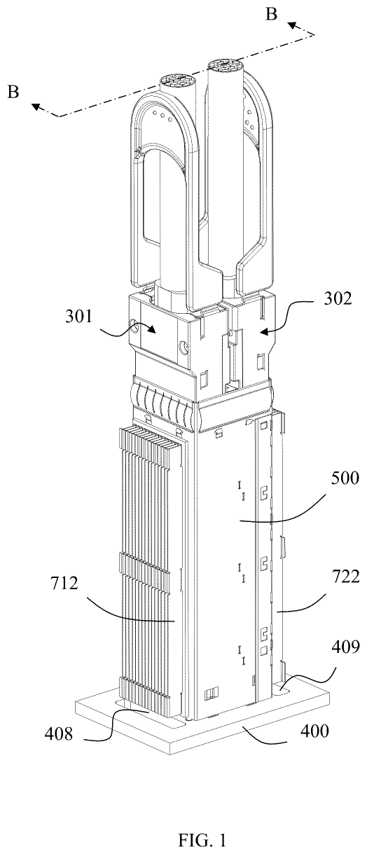

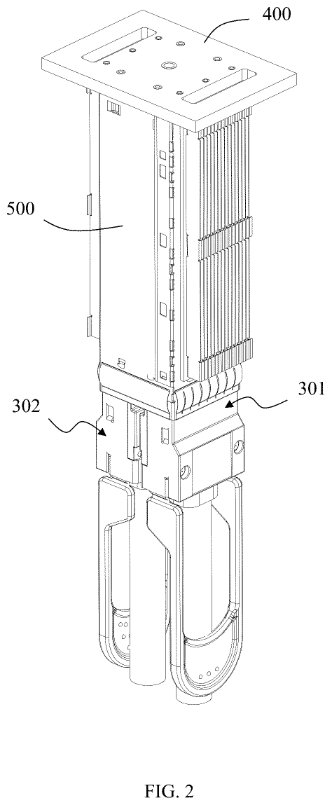

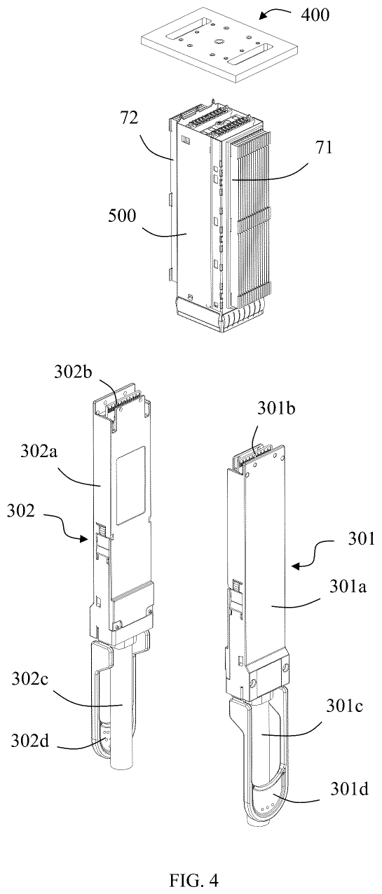

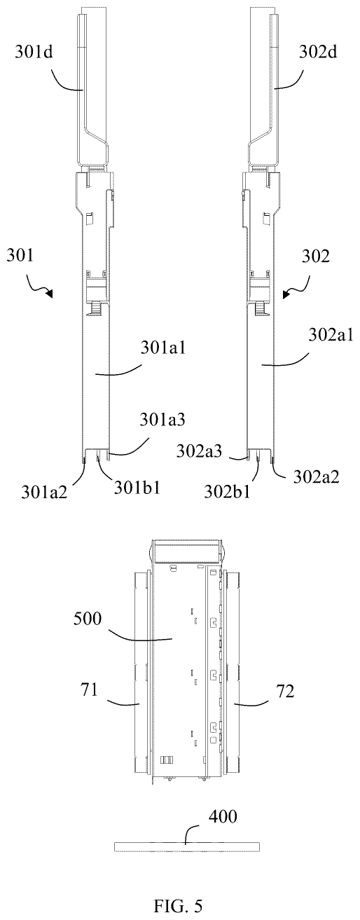

Referring to FIG. 1 to FIG. 5, the illustrated embodiment of the present disclosure discloses a connector assembly, which includes a circuit board 400, a first electrical connector 100 mounted to the circuit board 400 and electrically connected to the circuit board 400, a second electrical connector 200 mounted to the circuit board 400 and electrically connected to the circuit board 400, a shielding cage assembly 500 fixed to the circuit board 400, a first mating connector 301 for at least partially being inserted into the shielding cage assembly 500 and mating with the first electrical connector 100, and a second mating connector 302 for at least partially being inserted into the shielding cage assembly 500 and mating with the second electrical connector 200. In the illustrated embodiment of the present disclosure, the first electrical connector 100 and the second electrical connector 200 are vertical electrical connectors. The first electrical connector 100 and the second electrical connector 200 are both mounted on the circuit board 400 along a first direction A1-A1 (for example, a top-bottom direction). The first direction A1-A1 is perpendicular to the circuit board 400. The first mating connector 301 and the second electrical connector 200 are plugged and unplugged from the corresponding first electrical connector 100 and the second electrical connector 200 along the first direction A1-A1.

In the illustrated embodiment of the present disclosure, the first electrical connector 100 is an OSFP (Octal Small Form-factor Pluggable) receptacle connector. Correspondingly, the first mating connector 301 is an OSFP plug connector. Of course, it is understandable to those skilled in the art that the first electrical connector 100 can also be an SFP (Small Form-factor Pluggable) receptacle connector, a QSFP (Quad Small Form-factor Pluggable) receptacle connector, a QSFP-DD (Quad Small Form-factor Pluggable-Double Density) receptacle connector, an SFP-DD (Small Form-factor Pluggable-Double Density) receptacle connector or a DSFP (Dual Chanel Small Form-factor Pluggable) receptacle connector, etc. Correspondingly, the first mating connector 301 is an SFP plug connector, a QSFP plug connector, a QSFP-DD plug connector, an SFP-DD plug connector or a DSFP plug connector, etc. It is understandable to those skilled in the art that the basic structure of the above types of the electrical connectors is regulated by corresponding association standards, and will not be described in detail here. Of course, it is understandable to those skilled in the art that the first electrical connector 100 can also be other types of electrical connectors, including but not limited to USB connectors, HDMI connectors, DisplayPort connectors, RJ45 connectors, Thunderbolt connectors, etc.

In the illustrated embodiment of the present disclosure, the second electrical connector 200 is the same as the first electrical connector 100. The installation angles of the second electrical connector 200 and the first electrical connector 100 may be the same or different. In the illustrated embodiment of the present disclosure, the installation angles of the second electrical connector 200 and the first electrical connector 100 are different. The second electrical connector 200 is rotated 180 degrees in a horizontal plane compared to the first electrical connector 100. Correspondingly, the second mating connector 302 is the same as the first mating connector 301. In the illustrated embodiment of the present disclosure, the first mating connector 301 and the second mating connector 302 have different mating angles with the first electrical connector 100 and the second electrical connector 200. In the illustrated embodiment of the present disclosure, the first mating connector 301 and the second mating connector 302 are arranged belly to belly in order to minimize interference between the two during plugging and unplugging.

It is understandable to those skilled in the art that in the illustrated embodiment of the present disclosure, the shielding cage assembly 500, the first electrical connector 100 and the second electrical connector 200 are respectively mounted to the circuit board 400. That is, there is no direct fixed relationship between the shielding cage assembly 500 and the first electrical connector 100. There is no direct fixed relationship between the shielding cage assembly 500 and the second electrical connector 200.

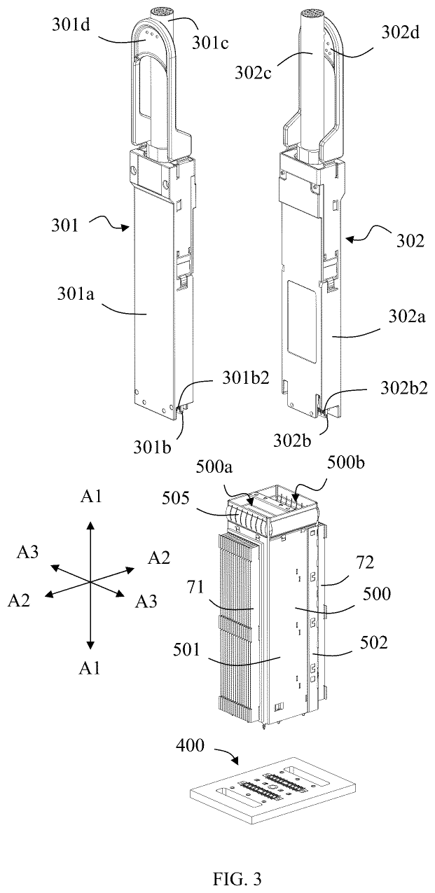

Referring to FIG. 3 to FIG. 5, the first mating connector 301 includes a first metal shell 301a, a first sub-circuit board 301b fixed in the first metal shell 301a, a first cable 301c electrically connected to the first sub-circuit board 301b, and a first unlocking pull strap 301d. The first metal shell 301a includes a first main body portion 301a1, a first extending tab 301a2 extending from the first main body portion 301al, and a first positioning tab 301a3 extending from the first main body portion 301a1. In the illustrated embodiment of the present disclosure, the first extending tab 301a2 and the first positioning tab 301a3 are located at a same end of the first mating connector 301. The first extending tab 301a2 is substantially parallel to the first positioning tab 301a3. The first sub-circuit board 301b includes a first tongue plate 301b1 located between the first extending tab 301a2 and the first positioning tab 301a3. A plurality of first conductive metal pads 301b2 are provided on two opposite surfaces of the first tongue plate 301b1. The first positioning tab 301a3 and the first extending tab 301a2 have different widths to prevent incorrect insertion. In the illustrated embodiment of the present disclosure, the first positioning tab 301a3 and the first extending tab 301a2 also have different thicknesses to prevent incorrect insertion.

The second mating connector 302 includes a second metal shell 302a, a second sub-circuit board 302b fixed in the second metal shell 302a, a second cable 302c electrically connected to the second sub-circuit board 302b, and a second unlocking pull strap 302d. The second metal shell 302a includes a second main body portion 302al, a second extending tab 302a2 extending from the second main body portion 302al, and a second positioning tab 302a3 extending from the second main body portion 302al. In the illustrated embodiment of the present disclosure, the second extending tab 302a2 and the second positioning tab 302a3 are located at a same end of the second mating connector 302. The second extending tab 302a2 is substantially parallel to the second positioning tab 302a3. The second sub-circuit board 302b includes a second tongue plate 302b1 located between the second extending tab 302a2 and the second positioning tab 302a3. A plurality of second conductive metal pads 302b2 are provided on two opposite surfaces of the second tongue plate 302b1. The second positioning tab 302a3 and the second extending tab 302a2 have different widths to prevent incorrect insertion. In the illustrated embodiment of the present disclosure, the second positioning tab 302a3 and the second extending tab 302a2 also have different thicknesses to prevent incorrect insertion.

In the illustrated embodiment of the present disclosure, the first mating connector 301 and the second mating connector 302 are arranged belly to belly. That is, the first mating connector 301 rotates 180 degrees in a horizontal plane relative to the second mating connector 302. The first unlocking pull strap 301d and the second unlocking pull strap 302d are disposed oppositely. That is, the first unlocking pull strap 301d and the second unlocking pull strap 302d can be disposed as far away from each other as possible. This arrangement enables the first unlocking pull strap 301d and the second unlocking pull strap 302d to be located outside their respective connectors, thereby preventing the first unlocking pull strap 301d and the second unlocking pull strap 302d from interfering with each other when pulling to unlock.

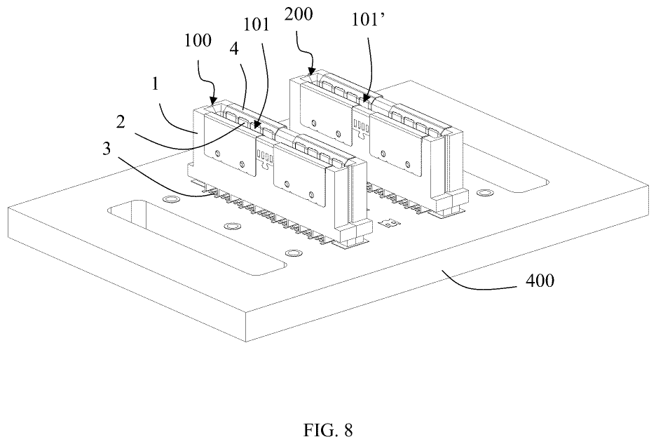

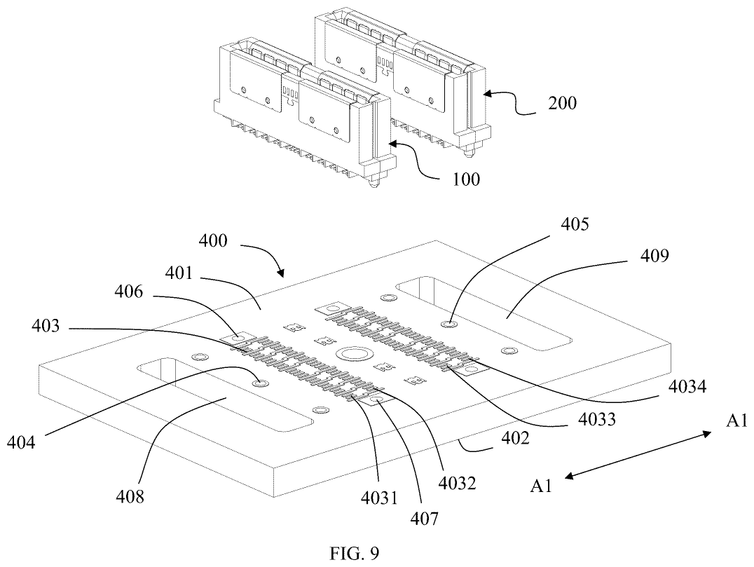

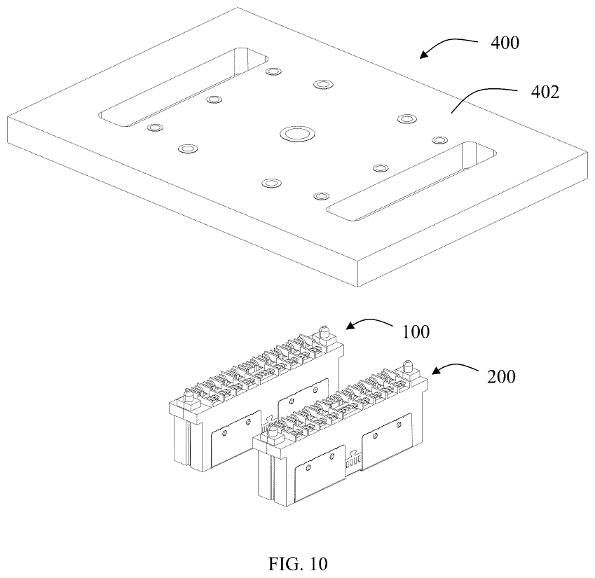

As shown in FIG. 8 to FIG. 10, the circuit board 400 includes a first surface 401 (for example, an upper surface), a second surface 402 (for example, a lower surface) disposed opposite to the first surface 401, a plurality of conductive pads 403 exposed on the first surface 401, a plurality of first mounting holes 404 extending through the first surface 401 and the second surface 402, a plurality of second mounting holes 405 extending through the first surface 401 and the second surface 402, a plurality of first positioning holes 406 extending through the first surface 401 and the second surface 402, a plurality of second positioning holes 407 extending through the first surface 401 and the second surface 402, a first heat dissipation slot 408 extending through the first surface 401 and the second surface 402, and a second heat dissipation slot 409 extending through the first surface 401 and the second surface 402. In one embodiment of the present disclosure, the circuit board 400 is a main circuit board on which a chip (not shown) and a plurality of electronic components (not shown) are mounted.

In the illustrated embodiment of the present disclosure, the plurality of conductive pads 403 include a first row of conductive pads 4031, a second row of conductive pads 4032, a third row of conductive pads 4033 and a fourth row of conductive pads 4034 which are sequentially arranged along the second direction A2-A2 (for example, a front-back direction). The first row of conductive pads 4031, the second row of conductive pads 4032, the third row of conductive pads 4033 and the fourth row of conductive pads 4034 are parallel to each other.

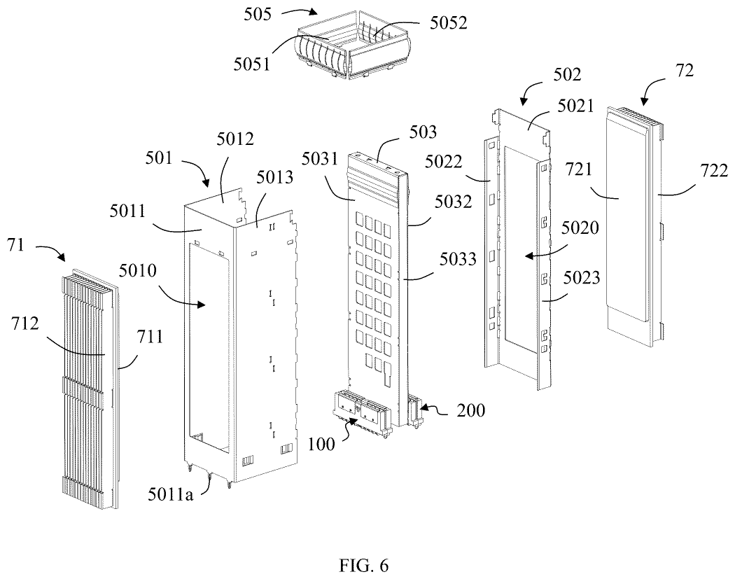

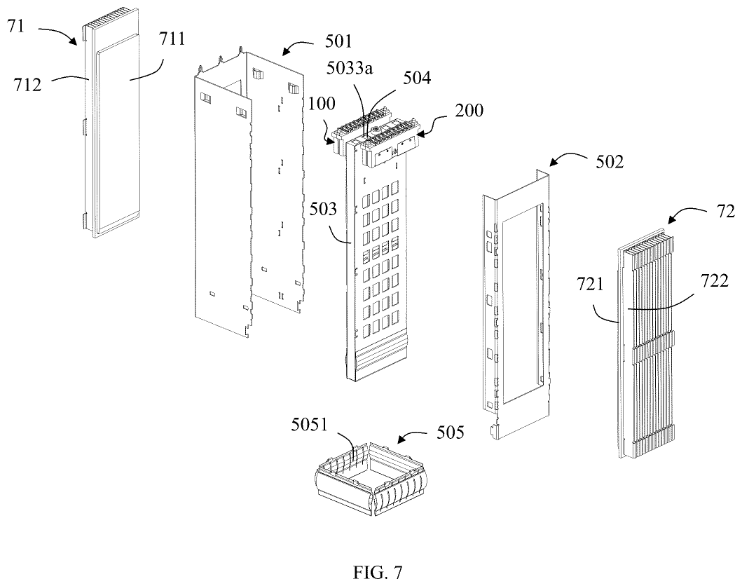

Referring to FIG. 6 and FIG. 7, in the illustrated embodiment of the present disclosure, the shielding cage assembly 500 includes a first metal shell 501, a second metal shell 502 buckled together with the first metal shell 501, and an intermediate metal shell 503 fixed to the first metal shell 501.

In the illustrated embodiment of the present disclosure, the first metal shell 501 is generally U-shaped and includes a first end wall 5011, a first side wall 5012 vertically bent from one end of the first end wall 5011, and a second side wall 5013 vertically bent from another end of the first end wall 5011. The first side wall 5012 and the second side wall 5013 are substantially parallel to each other. The first end wall 5011 defines a first opening 5010.

The second metal shell 502 is also generally U-shaped and includes a second end wall 5021, a first retaining wall 5022 vertically bent from one end of the second end wall 5021, and a second retaining wall 5023 vertically bent from another end of the second end wall 5021. The second end wall 5021 defines a second opening 5020. In the illustrated embodiment of the present disclosure, the second metal shell 502 and the first metal shell 501 have asymmetric structures.

In an embodiment of the present disclosure, a bottom of the second end wall 5021 is not in contact with the circuit board 400, which facilitates the wiring of the circuit board 400 and reduces the risk of short circuit. Even, a gap located between the second end wall 5021 and the circuit board 400 can provide space for electronic components on the circuit board 400.

In another embodiment of the present disclosure, the bottom of the second end wall 5021 is in contact with the circuit board 400, for example, in contact with a ground trace on the circuit board 400. Such an arrangement is beneficial to improving the grounding effect between the second end wall 5021 and the circuit board 400.

During assembly, the first retaining wall 5022 is buckled and fixed to the first side wall 5012, and the second retaining wall 5023 is buckled and fixed to the second side wall 5013. After assembly, the first end wall 5011, the first side wall 5012, the second side wall 5013 and the second end wall 5021 jointly form a receiving cavity. In the illustrated embodiment of the present disclosure, the shielding cage assembly 500 is in an elevated vertical shape. Specifically, the first end wall 5011, the first side wall 5012, and the second side wall 5013 all have the same first height along the first direction A1-A1. The first side wall 5012 and the second side wall 5013 both have the same first length along the second direction A2-A2. The first end wall 5011 and the second end wall 5021 both have the same first width along the third direction A3-A3. In the illustrated embodiment of the present disclosure, the first height is greater than the first length, and the first height is greater than the first width. The first length is greater than the first width. In the illustrated embodiment of the present disclosure, the first height is greater than at least twice the first length.

The shielding cage assembly 500 of the present disclosure is in the elevated vertical shape. The first height is greater than the first length. The first height is greater than the first width. Compared with the prior art in which the shielding cage assembly is disposed parallel to the circuit board, the arrangement of the present disclosure is beneficial to saving an occupied area of the circuit board 400. Under the same conditions, the arrangement of the present disclosure is beneficial to enabling the circuit board 400 to install more electronic components. At the same time, the shielding cage assembly 500 of the present disclosure may be prone to the risk of tilting under the action of external force due to its high height. The illustrated embodiment of the present disclosure will also specifically elaborate on how to solve the above technical problem, which will be described in detail later.

The first metal shell 501 further includes a plurality of first fixing feet 5011a protruding downwardly from a bottom edge of the first end wall 5011 along the first direction

A1-A1. In the illustrated embodiment of the present disclosure, each first fixing foot 5011a is in a fish-eye shape, so that the first fixing foot 5011a has a certain elastic deformation ability. The first fixing foot 5011a is configured to be pressed into the first mounting hole 404 of the circuit board 400 to be fixed with the circuit board 400 and achieve electrical connection (for example, grounding).

As shown in FIG. 6 and FIG. 7, the intermediate metal shell 503 includes a first clamping plate 5031, a second clamping plate 5032, and an intermediate plate 5033 located between the first clamping plate 5031 and the second clamping plate 5032. Each of the first clamping plate 5031 and the second clamping plate 5032 defines a plurality of heat dissipation holes. The intermediate plate 5033 is a metal plate that is integral and has a relatively large thickness. The intermediate plate 5033 defines a plurality of receiving channels 5033a for receiving light guide pipes 504. The intermediate plate 5033 is configured to cooperate with a fastener (for example, a bolt) to reliably install the shielding cage assembly 500 on the circuit board 400, thereby avoiding the risk that the shielding cage assembly 500 will easily tilt under the action of external force due to its high height.

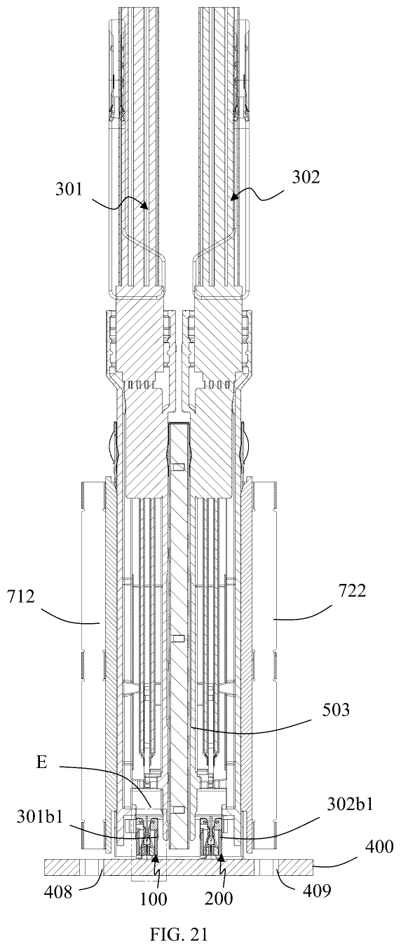

Referring to FIG. 3, FIG. 6, FIG. 7 and FIG. 21, the intermediate metal shell 503 divides the receiving cavity into a first receiving cavity 500a and a second receiving cavity 500b which are located on two sides of the intermediate metal shell 503, respectively. The first receiving cavity 500a and the first receiving slot 101 of the first electrical connector 100 are in communication to jointly receive the first mating connector 301. The first main body portion 301al of the first mating connector 301 is generally received in the first receiving cavity 500a. The first tongue plate 301b1 of the first mating connector 301 is inserted into the first receiving slot 101.

Similarly, the second receiving cavity 500b and the second receiving slot 101′ of the second electrical connector 200 are in communication to receive the second mating connector 302. The second main body portion 302al of the second mating connector 302 is generally received in the second receiving cavity 500b. The second tongue plate 302b1 of the second mating connector 302 is inserted into the second receiving slot 101′.

In the illustrated embodiment of the present disclosure, the shielding cage assembly 500 further includes an abutting elastic arm 505 fixed to the first metal shell 501 and the second metal shell 502. The abutting elastic arm 505 includes a first abutting elastic arm 5051 protruding into the first receiving cavity 500a, and a second abutting elastic arm 5052 protruding into the second receiving cavity 500b. The first abutting elastic arm 5051 is configured to abut against the first mating connector 301 to increase the holding force and improve the grounding effect. The second abutting elastic arm 5052 is configured to abut against the second mating connector 302 to increase the holding force and improve the grounding effect.

In the illustrated embodiment of the present disclosure, the connector assembly 100 further includes at least one heat sink installed on the shielding cage assembly 500. Referring to FIG. 1 to FIG. 7, in the illustrated embodiment of the present disclosure, the at least one heat sink includes a first heat sink 71 fixed on the first end wall 5011 and a second heat sink 72 fixed on the second end wall 5021.

In one embodiment of the present disclosure, the first heat sink 71 includes a first body portion 711 and a plurality of first heat dissipation fins 712 protruding sidewardly from the first body portion 711. In one embodiment of the present disclosure, the first body portion 711 is fixed on an outside of the first end wall 5011. The plurality of first heat dissipation fins 712 protrude outwardly beyond the first end wall 5011. The plurality of first heat dissipation fins 712 are equally spaced along the third direction A3-A3. In the illustrated embodiment of the disclosure, the first body portion 711 is fixed to the outside of the first end wall 5011 by soldering or welding. The first body portion 711 at least partially extends inwardly into the first opening 5010 and is exposed in the first receiving cavity 500a. The first body portion 711 is configured to be in contact with the first main body portion 301al of the first mating connector 301 to achieve better heat dissipation of the first mating connector 301.

Similarly, in one embodiment of the present disclosure, the second heat sink 72 includes a second body portion 721 and a plurality of second heat dissipation fins 722 protruding sidewardly from the second body portion 721. In one embodiment of the present disclosure, the second body portion 721 is fixed on an outside of the second end wall 5021. The plurality of second heat dissipation fins 722 protrude outwardly beyond the second end wall 5021. The plurality of second heat dissipation fins 722 are equally spaced along the third direction A3-A3. In the illustrated embodiment of the present disclosure, the second body portion 721 is fixed to the outside of the second end wall 5021 by soldering or welding. The second body portion 721 at least partially extends inwardly into the second opening 5020 and is exposed in the second receiving cavity 500b. The second body portion 721 is configured to be in contact with the second main body portion 302al of the second mating connector 302 to achieve better heat dissipation of the second mating connector 302.

Referring to FIG. 1, in the illustrated embodiment of the present disclosure, the first heat sink 71 and the second heat sink 72 are both spaced apart a certain distance from the circuit board 400 along the first direction A1-A1. In the illustrated embodiment of the present disclosure, the first heat dissipation fins 712 correspond to the first heat dissipation slot 408 and are located above the first heat dissipation slot 408. The second heat dissipation fins 722 correspond to the second heat dissipation slot 409 and are located above the second heat dissipation slot 409. As a result, better heat dissipation can be facilitated.

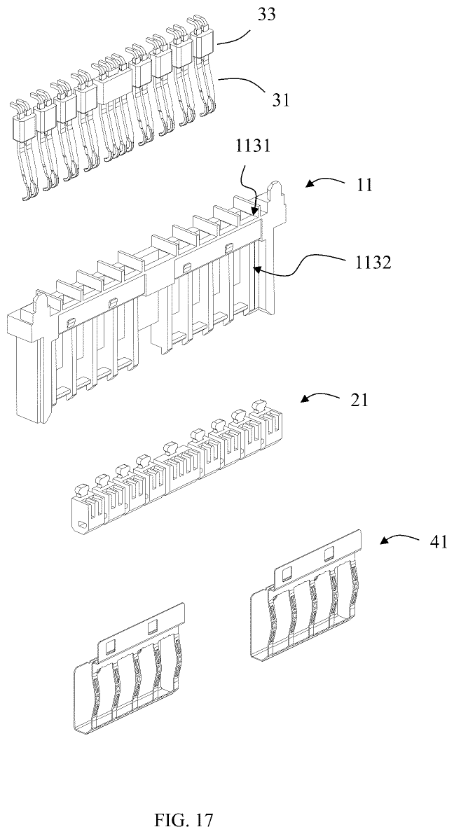

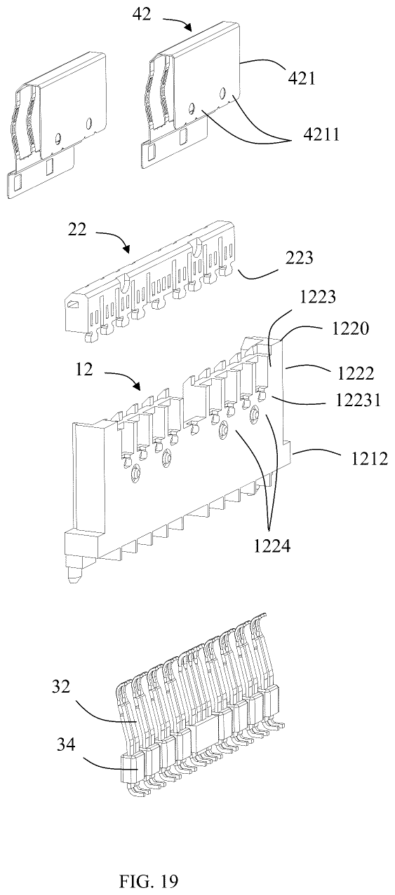

Referring to FIG. 8 to FIG. 20, in the illustrated embodiment of the present disclosure, the first electrical connector 100 defines a first receiving slot 101 for at least partially receiving the first mating connector 301. To simplify the description of the specific embodiments of the present disclosure, an insertion and extraction direction of the first mating connector 301 and the first electrical connector 100 is the first direction A1-A1 (for example, a top-bottom direction); a thickness direction of the first receiving slot 101 is the second direction A2-A2 (for example, a front-back direction); a width direction of the first receiving slot 101 is the third direction A3-A3 (for example, a left-right direction). Each two of the first direction A1-A1, the second direction A2-A2 and the third direction A3-A3 are perpendicular to each other.

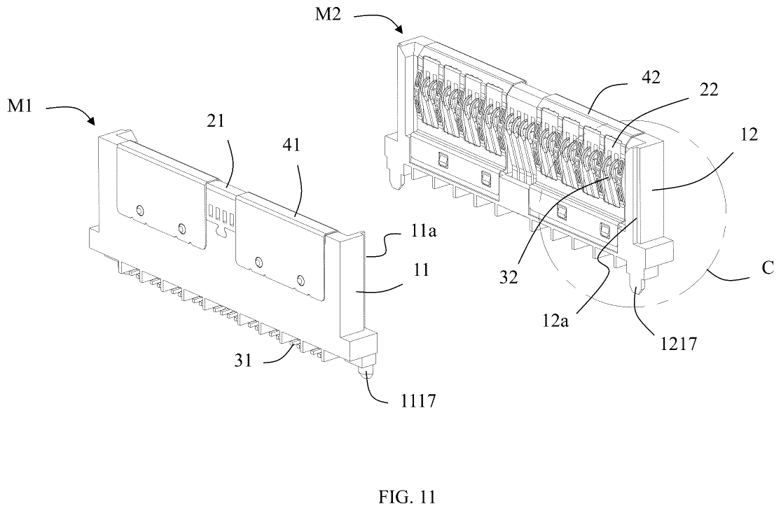

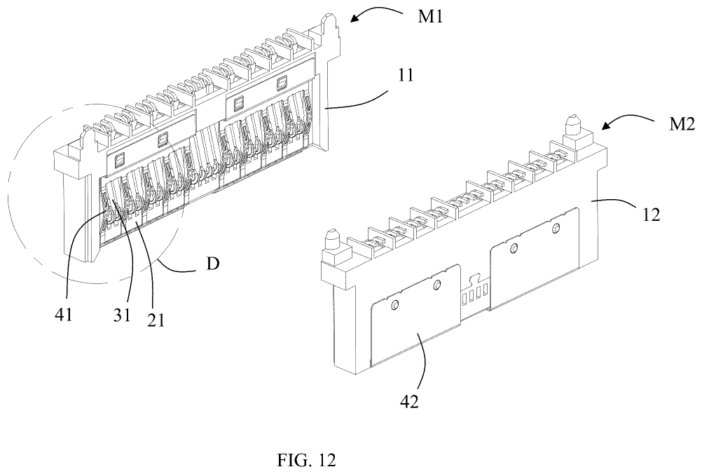

Referring to FIG. 11 and FIG. 12, in the illustrated embodiment of the present disclosure, the first electrical connector 100 includes a first module M1 and a second module M2. The first module M1 and the second module M2 are separately arranged and fixed together. Preferably, the first module M1 and the second module M2 are the same part, but have different installation angles to save costs.

In the illustrated embodiment of the present disclosure, the first electrical connector 100 and the second electrical connector 200 have the same structure. The following description only takes the first electrical connector 100 as an example. Referring to FIG. 8, in one embodiment of the present disclosure, the first electrical connector 100 includes a housing, an insulating fixing block 2 fixed to the housing, and a plurality of conductive terminals 3 installed to the housing.

In an embodiment of the present disclosure, the housing is a conductive housing 1. The conductive housing 1 is a metal housing made of metal material so as to further improve the shielding effect and improve the quality of signal transmission. In another embodiment of the present disclosure, the conductive housing 1 may also be a composite housing formed by electroplating a metal material on an insulating material. The composite housing can also improve the shielding effect and improve the quality of signal transmission.

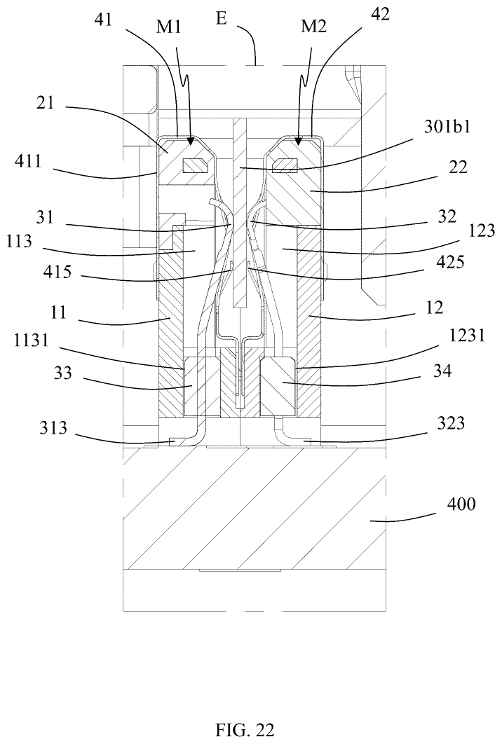

Referring to FIG. 11 to FIG. 22, in an embodiment of the present disclosure, the conductive housing 1 includes a first conductive housing 11 and a second conductive housing 12. The first conductive housing 11 and the second conductive housing 12 are fixed together. For example, after the first conductive housing 11 and the second conductive housing 12 are assembled, they are fixed together for example by welding or soldering or other methods. In the illustrated embodiment of the present disclosure, the first conductive housing 11 of the first module M1 and the second conductive housing 12 of the second module M2 are separately arranged and fixed together to jointly form the first receiving slot 101. In order to simplify the description, the position of the first module M1 and the second module M2 close to the first receiving slot 101 is called “inner”, and the position far from the first receiving slot 101 is called “outer”.

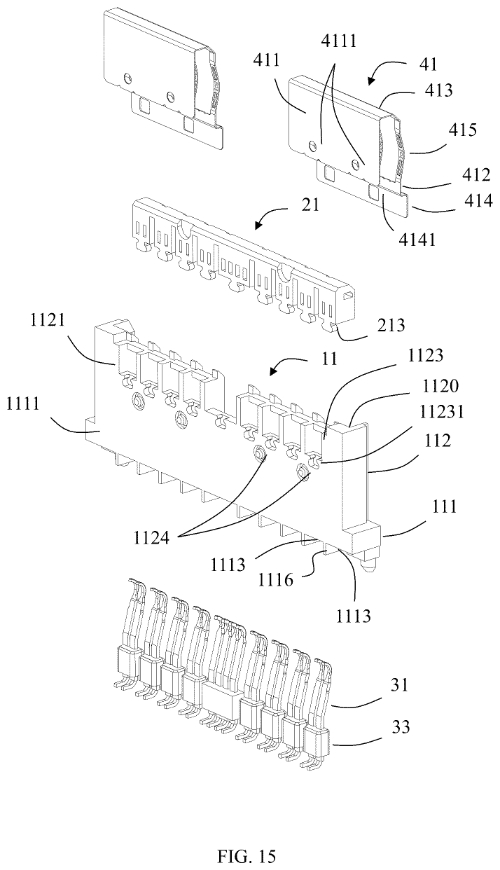

Referring to FIG. 15 to FIG. 17, in an embodiment of the present disclosure, the first conductive housing 11 includes a first base portion 111 and a first protruding portion 112 extending upwardly from the first base portion 111. The first base portion 111 includes a first outer surface 1111, a first inner surface 1112, and a plurality of first mounting grooves 1116 extending along the first direction A1-A1. The plurality of first mounting grooves 1116 are spaced apart along the third direction A3-A3. In the illustrated embodiment of the present disclosure, the first base portion 111 is further provided with a plurality of first barrier portions 1113. Any two adjacent first mounting grooves 1116 are separated by one first barrier portion 1113 located between the two first mounting grooves 1116 so as to improve the shielding effect and improve the quality of signal transmission. Besides, a top of the first base portion 111 further includes at least one first recess 1118 adjacent to the first protruding portion 112. In the illustrated embodiment of the present disclosure, two first recesses 1118 are provided. The first base portion 111 further includes a plurality of first mounting protrusions 1119 protruding into corresponding first recesses 1118. A bottom of the first base portion 111 is further provided with a plurality of first positioning protruding posts 1117 extending downwardly along the first direction A1-A1.

Referring to FIG. 15 to FIG. 17, the first protruding portion 112 includes a second outer surface 1121, a second inner surface 1122, and a plurality of first filling grooves 1123 extending outwardly through the second outer surface 1121 along the second direction A2-A2. The first filling grooves 1123 extend forwardly through a first top end surface 1120 of the first protruding portion 112 along the first direction A1-A1. The first protruding portion 112 further includes a plurality of first positioning posts 1124 protruding outwardly beyond the second outer surface 1121 along the second direction A2-A2.

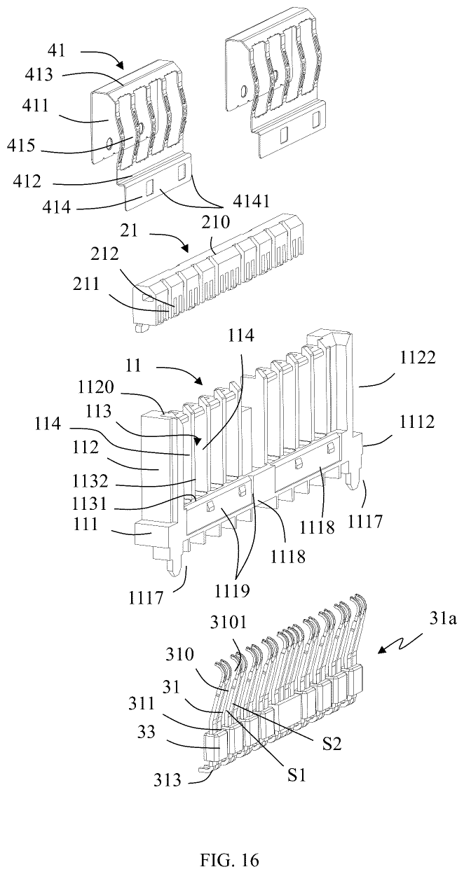

Referring to FIG. 16, in the illustrated embodiment of the present disclosure, the first conductive housing 11 further includes a plurality of first terminal module installation slots 113 extending along the first direction A1-A1. Each first terminal module installation slot 113 extends from a portion of the first base portion 111 to the first protruding portion 112. A bottom end of the first terminal module installation slot 113 communicates with the first mounting groove 1116. A middle portion of the first terminal module installation slot 113 is circumferentially surrounded by walls of the first conductive housing 11. A top end of the first terminal module installation slot 113 extends inwardly through the second inner surface 1122. Specifically, in the illustrated embodiment of the present disclosure, the first terminal module installation slot 113 includes a first surrounding groove 1131 close to a corresponding first mounting groove 1116 and a first open slot 1132 away from the corresponding first mounting groove 1116. The first surrounding groove 1131 is surrounded by wall portions of the first conductive housing 11 along a circumferential direction. The first open slot 1132 communicates with the first receiving slot 101. It is understandable to those skilled in the art that by arranging the middle portion of the first terminal module installation slot 113 to be surrounded by the wall portions of the first conductive housing 11 in a circumferential direction, on the one hand, the conductive terminals located in the first terminal module installation slots 113 can be better shielded; and on the other hand, adjacent first terminal module installation slots 113 can be well separated, thereby reducing signal crosstalk.

As shown in FIG. 16, the plurality of first terminal module installation slots 113 are spaced apart along the third direction A3-A3. The first conductive housing 11 includes a plurality of first partition walls 114 disposed at intervals along the third direction A3-A3. Two adjacent first terminal module installation slots 113 are separated by a corresponding first partition wall 114 along the third direction A3-A3. In other words, each first terminal module installation slot 113 is surrounded by four walls of the first conductive housing 11 on a length corresponding to the corresponding first partition wall 114, thereby improving the shielding effect. With this arrangement, each first terminal module installation slot 113 is relatively independent, thereby reducing signal crosstalk and improving the quality of data transmission.

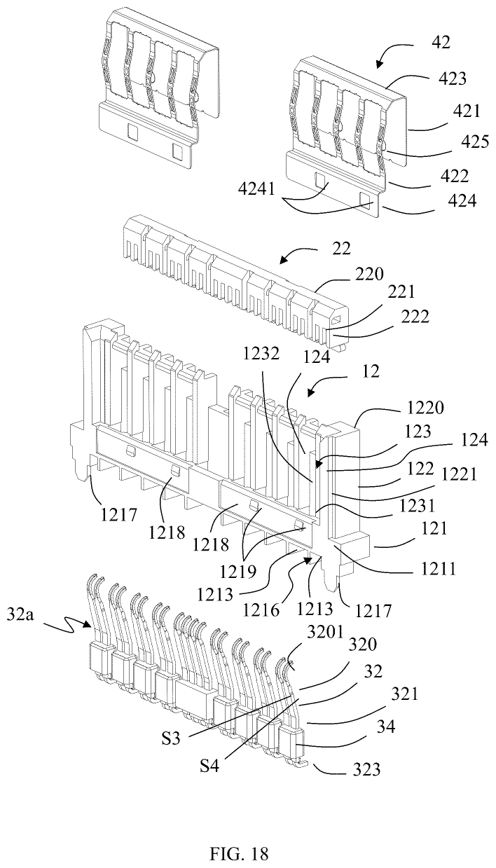

Referring to FIG. 18 to FIG. 20, in an embodiment of the present disclosure, the second conductive housing 12 includes a second base portion 121 and a second protruding portion 122 extending upwardly from the second base portion 121. The second base portion 121 includes a third outer surface 1211, a third inner surface 1212, and a plurality of second mounting grooves 1216 extending along the first direction A1-A1. The plurality of second mounting grooves 1216 are spaced apart along the third direction A3-A3. In the illustrated embodiment of the present disclosure, the second base portion 121 is further provided with a plurality of second barrier portions 1213. Any two adjacent second mounting grooves 1216 are separated by one second barrier portion 1213 located between the two second mounting grooves 1216 to improve the shielding effect and improve the quality of signal transmission. Besides, a top of the second base portion 121 further defines at least one second recess 1218 adjacent to the second protruding portion 122. In the illustrated embodiment of the present disclosure, two second recesses 1218 are provided. The second base portion 121 further includes a plurality of second mounting protrusions 1219 protruding into corresponding second recesses 1218. A bottom of the second base portion 121 is further provided with a plurality of second positioning protruding posts 1217 extending downwardly along the first direction A1-A1.

Referring to FIG. 18 to FIG. 20, the second protruding portion 122 includes a fourth inner surface 1221, a fourth outer surface 1222, and a plurality of second filling grooves 1223 extending outwardly through the fourth outer surface 1222. The second filling grooves 1223 extend upwardly through a second top end surface 1220 of the second protruding portion 122.

The second protruding portion 122 further includes a plurality of second positioning posts 1224 protruding outwardly beyond the second inner surface 1122.

Referring to FIG. 16, in the illustrated embodiment of the present disclosure, the second conductive housing 12 further includes a plurality of second terminal module installation slots 123 extending along the first direction A1-A1. Each second terminal module installation slot 123 extends from the second base portion 121 to the second protruding portion 122. A bottom end of the second terminal module installation slot 123 communicates with the second mounting groove 1216. The middle portion of the second terminal module installation slot 123 is circumferentially surrounded by walls of the second conductive housing 12. A top end of the second terminal module installation slot 123 extends inwardly through the fourth inner surface 1221. Specifically, in the illustrated embodiment of the present disclosure, the second terminal module installation slot 123 includes a second surrounding groove 1231 close to a corresponding second mounting groove 1216 and a second open slot 1232 away from the corresponding second mounting groove 1216. The second surrounding groove 1231 is surrounded by wall portions of the second conductive housing 12 along a circumferential direction. The second open slot 1232 communicates with the first receiving slot 101. It is understandable to those skilled in the art that by arranging the middle portion of the second terminal module installation slot 123 to be surrounded by the wall portions of the second conductive housing 12 in a circumferential direction; on the one hand, the conductive terminals located in the second terminal module installation slots 123 can be better shielded; and on the other hand, the adjacent second terminal module installation slots 123 can be well separated, thereby reducing signal crosstalk.

As shown in FIG. 18, the plurality of second terminal module installation slots 123 are arranged at intervals along the third direction A3-A3. The second conductive housing 12 includes a plurality of second partition walls 124 disposed at intervals along the third direction A3-A3. Two adjacent second terminal module installation slots 123 are separated by corresponding second partition walls 124 along the third direction A3-A3. In other words, each second terminal module installation slot 123 is surrounded by four walls of the second conductive housing 12 on a length corresponding to the second partition wall 124, thereby improving the shielding effect. With this arrangement, each second terminal module installation slot 123 is relatively independent, thereby reducing signal crosstalk and improving the quality of data transmission.

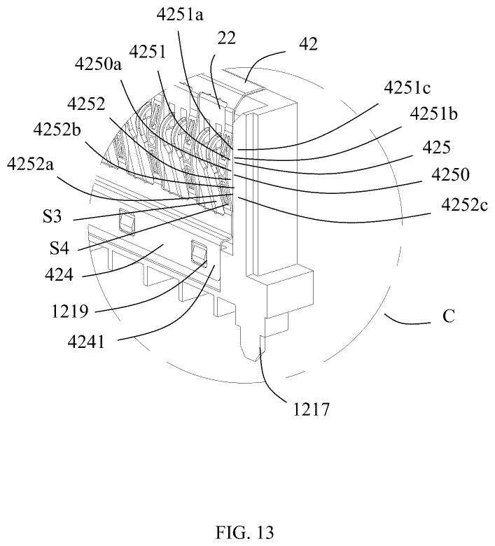

Referring to FIG. 13 to FIG. 22, in the illustrated embodiment of the present disclosure, the insulating fixing block 2 includes a first insulating fixing block 21 and a second insulating fixing block 22. The first insulating fixing block 21 is fixed in the first filling grooves 1123. The second insulating fixing block 22 is fixed in the second filling grooves 1223. Preferably, in order to increase the bonding force between the first insulating fixing block 21 and the first conductive housing 11, the first insulating fixing block 21 is molded in the first filling grooves 1123. Similarly, in order to increase the bonding force between the second insulating fixing block 22 and the second conductive housing 12, the second insulating fixing block 22 is molded in the second filling grooves 1223. The first insulating fixing block 21 is provided with a first dovetail protrusion 213. The first filling groove 1123 is provided with a first dovetail groove 11231. When the first dovetail protrusion 213 is clamped into the first dovetail groove 11231, the first insulating fixing block 21 can be prevented from falling off from the first conductive housing 11 in the first direction A1-A1. Similarly, the second insulating fixing block 22 is provided with a second dovetail protrusion 223. The second filling groove 1223 is provided with a second dovetail groove 12231. When the second dovetail protrusion 223 is clamped into the second dovetail groove 12231, the second insulating fixing block 22 can be prevented from falling off from the second conductive housing 12 in the first direction A1-A1.

The first insulating fixing block 21 defines a plurality of first slits 211 and a plurality of second slits 212, in which adjacent first slit 211 and second slit 212 form a group and communicate with a corresponding first terminal module installation slot 113. The first insulating fixing block 21 further includes a first top surface 210 which is coplanar with the first top end surface 1120 of the first protruding portion 112.

Similarly, the second insulating fixing block 22 defines a plurality of third slits 221 and a plurality of fourth slits 222. Adjacent third slit 221 and fourth slit 222 form a group and communicate with a corresponding second terminal module installation slot 123. The second insulating fixing block 22 includes a second top surface 220 which is coplanar with the second top end surface 1220 of the second protruding portion 122.

As shown in FIG. 13 to FIG. 20, the plurality of conductive terminals 3 include a plurality of first conductive terminals 31 and a plurality of second conductive terminals 32. Each first conductive terminal 31 includes a first fixing portion 311 extending along the first direction A1-A1, a first contact arm 310 extending upwardly from a top end of the first fixing portion 311, and a first tail portion 313 bent from a bottom end of the first fixing portion 311. The first fixing portion 311 is at least partially located in the first surrounding groove 1131. The first contact arm 310 is at least partially located in the first open slot 1132. The first tail portion 313 is at least partially located in the first mounting groove 1116. The first contact arm 310 includes a first contact portion 3101 that passes through the first open slot 1132 and extends into the first receiving slot 101. The first contact portions 3101 are configured to be in contact with the first tongue plate 301b1 of the first mating connector 301 so as to achieve electrical connection. In the illustrated embodiment of the present disclosure, the first tail portion 313 extends horizontally outward to be electrically connected to the first row of conductive pads 4031 of the circuit board 400. For example, the first tail portions 313 are fixed to the first row of conductive pads 4031 of the circuit board 400 by soldering or welding.

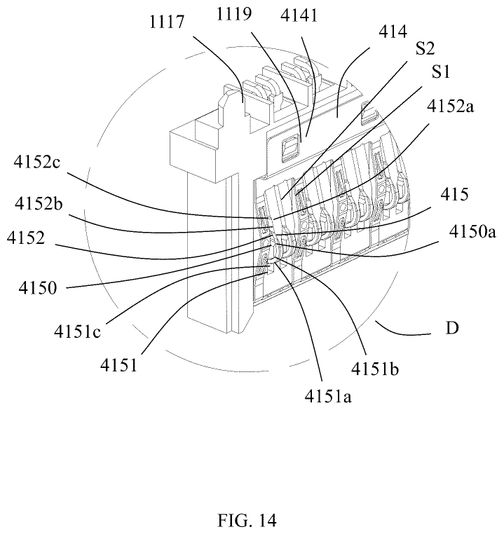

Referring to FIG. 14, in the illustrated embodiment of the present disclosure, the plurality of first conductive terminals 31 are divided into a plurality of groups. Each group of first conductive terminals 31 includes a first signal terminal S1 and a second signal terminal S2 located adjacent to the first signal terminal S1. Preferably, the first signal terminal S1 and the second signal terminal S2 in each group of first conductive terminals 31 form a differential pair to improve signal transmission speed, thereby being suitable for high-speed signal transmission.

In the illustrated embodiment of the present disclosure, the first electrical connector 100 further includes a first holding block 33 fixed on the first signal terminal S1 and the second signal terminal S2 of each group of first conductive terminals 31. In an embodiment of the present disclosure, the first signal terminal S1 and the second signal terminal S2 are insert-molded with the first holding block 33, so as to form an integrated first terminal module 31a. The first contact portions 3101 of the first signal terminal S1 and the second signal terminal S2 in each first terminal module 31a are configured to be in contact with the first conductive metal pads 301b2 of the first mating connector 301, respectively.

In the illustrated embodiment of the present disclosure, the first holding block 33 is installed and fixed in the first terminal module installation slot 113, which prevents the first conductive terminals 31 from contacting the first conductive housing 11 to cause a short circuit. The first tail portion 313 extends outwardly into the first mounting groove 1116 to improve the shielding effect.

Similarly, referring to FIG. 18 to FIG. 20, each second conductive terminal 32 includes a second fixing portion 321 extending along the first direction A1-A1, a second contact arm 320 extending upwardly from a top end of the second fixing portion 321, and a second tail portion 323 extending outwardly from a bottom end of the second fixing portion 321. The second fixing portion 321 is at least partially located in the second surrounding groove 1231. The second contact arm 320 is located at least partially in the second open slot 1232. The second tail portion 323 is at least partially located in the second mounting groove 1216. The second contact arm 320 includes a second contact portion 3201 that passes through the second open slot 1232 and extends into the first receiving slot 101. The second contact portions 3201 are configured to be in contact with the first conductive metal pads 301b2 of the tongue plate 301. In the illustrated embodiment of the present disclosure, the second tail portions 323 extend outwardly and horizontally from the second fixing portions 321 to be electrically connected to the second row of conductive pads 4032 of the circuit board 400. For example, the second tail portions 323 are fixed to the second row of conductive pads 4032 of the circuit board 400 by soldering or welding.

In the illustrated embodiment of the present disclosure, the plurality of second conductive terminals 32 are divided into a plurality of groups, and each group of second conductive terminals 32 includes a third signal terminal S3 and a fourth signal terminal S4 located adjacent to the third signal terminal S3. Preferably, the third signal terminal S3 and the fourth signal terminal S4 in each group of second conductive terminals 32 form a differential pair to improve signal transmission speed, thereby being suitable for high-speed signal transmission.

In the illustrated embodiment of the present disclosure, the first electrical connector 100 further includes a second holding block 34 fixed on the third signal terminal S3 and the fourth signal terminal S4 of each group of second conductive terminals 32. In one embodiment of the present disclosure, the third signal terminal S3 and the fourth signal terminal S4 are insert-molded with the second holding block 34 to form an integrated second terminal module 32a. The second contact portions 3201 of the third signal terminal S3 and the fourth signal terminal S4 in each second terminal module 32a are configured to be in contact with the first conductive metal pads 301b2 of the first mating connector 301.

In the illustrated embodiment of the present disclosure, the second holding block 34 is installed and fixed in the second terminal module installation slot 123, which prevents the second conductive terminals 32 from contacting the second conductive housing 12 to cause a short circuit. The second tail portions 323 extend outwardly into the second mounting grooves 1216 to improve the shielding effect.

Referring to FIG. 8 to FIG. 22, in one embodiment of the present disclosure, the first electrical connector 100 further includes at least one ground sheet 4 mounted to the conductive housing 1. The ground sheet 4 includes a first ground sheet 41 and a second ground sheet 42. In the illustrated embodiment of the present disclosure, two first ground sheets 41 are provided and they are made of metal material. Two second ground sheets 42 are provided and they are made of metal material.

Referring to FIG. 15 to FIG. 17, each first ground sheet 41 is generally U-shaped and includes a first mounting plate 411, a second mounting plate 412 opposite to the first mounting plate 411, a first connecting plate 413 connecting one side of the first mounting plate 411 and one side of the second mounting plate 412, and a first extension plate 414 extending from another side of the second mounting plate 412. The first mounting plate 411 defines a plurality of first mounting positioning holes 4111 that match the first positioning posts 1124. The first extension plate 414 is received in a corresponding first recess 1118 of the first conductive housing 11. The first extension plate 414 defines a plurality of first mounting holes 4141 to receive the first mounting protrusions 1119.

The first connecting plate 413 abuts against and at least partially covers the first top surface 210 of the first insulating fixing block 21. The first connecting plate 413 is located at a top end of the first receiving slot 101 along the first direction A1-A1. When the first mating connector 301 is inserted, the first mating connector 301 may be in contact with the first connecting plate 413 first, thereby facilitating the discharge of static electricity. The second mounting plate 412 is provided with a plurality of first grounding elastic arms 415 which are disposed at intervals along the second direction A2-A2. The first grounding elastic arms 415 are disposed on two sides of the first contact arms 310 of each group of first conductive terminals 31 so as to improve the shielding effect and improve the quality of signal transmission.

The first grounding elastic arm 415 as a whole bulges inwardly away from the first mounting plate 411. Specifically, in the illustrated embodiment of the present disclosure, the first grounding elastic arm 415 includes a first intermediate portion 4150, a first elastic arm portion 4151 connecting one end of the first intermediate portion 4150 and the first connecting plate 413, and a second elastic arm portion 4152 connecting another end of the first intermediate portion 4150 and the first extension plate 414. In one embodiment of the present disclosure, the first intermediate portion 4150 includes a first dimple 4150a protruding into the first receiving slot 101. The first elastic arm portion 4151 is provided with a first contact elastic arm 4151a extending toward the first intermediate portion 4150, and a first relief groove 4151b corresponding to the first contact elastic arm 4151a and providing a deformation space for the first contact elastic arm 4151a. The second elastic arm portion 4152 is provided with a second contact elastic arm 4152a extending toward the first intermediate portion 4150, and a second relief groove 4152b corresponding to the second contact elastic arm 4152a and providing a deformation space for the second contact elastic arm 4152a. In the illustrated embodiment of the present disclosure, the first contact elastic arm 4151a and the second contact elastic arm 4152a are located on two sides of the first intermediate portion 4150, respectively. The first contact elastic arm 4151a and the second contact elastic arm 4152a are aligned along the first direction A1-A1. A free end of the first contact elastic arm 4151a and a free end of the second contact elastic arm 4152a are both located adjacent to the first intermediate portion 4150. The first contact elastic arm 4151a, the first dimple 4150a and the second contact elastic arm 4152a are all in contact with the first mating connector 301. This three-point contact method is beneficial to achieve better shielding effect.

In one embodiment of the present disclosure, the first elastic arm portion 4151 includes a first frame 4151c that is surrounded by all sides. The first relief groove 4151b is a closed groove and is surrounded by the first frame 4151c. The first contact elastic arm 4151a is connected to a wall of the first frame 4151c. The other three walls of the first frame 4151c respectively surround the other three sides of the first contact elastic arm 4151a. In an embodiment of the present disclosure, by arranging the first frame 4151c surrounding the first contact elastic arm 4151a, it can provide better protection for the first contact elastic arm 4151a and prevent the first contact elastic arm 4151a from being excessively deformed.

Similarly, the second elastic arm portion 4152 includes a second frame 4152c that is surrounded by all sides. The second relief groove 4152b is a closed groove and is surrounded by the second frame 4152c. The second contact elastic arm 4152a is connected to a wall of the second frame 4152c. The other three walls of the second frame 4152c respectively surround the other three sides of the second contact elastic arm 4152a. In one embodiment of the present disclosure, by arranging the second frame 4152c surrounding the second contact elastic arm 4152a, it can provide better protection for the second contact elastic arm 4152a and prevent the second contact elastic arm 4152a from being excessively deformed.

In an embodiment of the present disclosure, the first positioning posts 1124 are fixed to the first mounting positioning holes 4111, so that the first mounting plate 411 is fixed to the second outer surface 1121 of the first protruding portion 112. As shown in FIG. 21, a dimension of the first mounting hole 4141 along the first direction A1-A1 may be slightly larger than a dimension of the first mounting protrusion 1119 along the first direction A1-A1. Therefore, when the first contact elastic arm 4151a, the first intermediate portion 4150 and the second contact elastic arm 4152a are contacted and deformed by the first mating connector 301, the first extension plate 414 can move appropriately in the first recess 1118 along the first direction A1-A1.

Referring to FIG. 18 to FIG. 20, each second ground sheet 42 is generally U-shaped and includes a third mounting plate 421, a fourth mounting plate 422 opposite to the third mounting plate 421, a second connecting plate 423 connecting one side of the third mounting plate 421 and one side of the fourth mounting plate 422, and a second extension plate 424 extending from another side of the fourth mounting plate 422. The third mounting plate 421 defines a plurality of second mounting positioning holes 4211 that match the second positioning posts 1224. The second extension plate 424 is received in a corresponding second recess 1218 of the second conductive housing 12. The second extension plate 424 defines a plurality of second mounting holes 4241 to receive the second mounting protrusions 1219.

The second connecting plate 423 abuts against and at least partially covers the second top surface 220 of the second insulating fixing block 22. The second connecting plate 423 is located at the top end of the first receiving slot 101 along the first direction A1-A1. When the first mating connector 301 is inserted, the first mating connector 301 may be in contact with the second connecting plate 423 first, thereby facilitating the discharge of static electricity. The fourth mounting plate 422 is provided with a plurality of second grounding elastic arms 425 which are disposed at intervals along the second direction A2-A2. The second grounding elastic arms 425 are disposed on two sides of the second contact arms 320 of each group of second conductive terminals 32, respectively, so as to improve the shielding effect and improve the quality of signal transmission.

The second grounding elastic arm 425 bulges inwardly away from the third mounting plate 421 as a whole. Specifically, in the illustrated embodiment of the present disclosure, the second grounding elastic arm 425 includes a second intermediate portion 4250, a third elastic arm portion 4251 connecting one end of the second intermediate portion 4250 and the second connecting plate 423, and a fourth elastic arm portion 4252 connecting another end of the second intermediate portion 4250 and the second extension plate 424. In one embodiment of the present disclosure, the second intermediate portion 4250 includes a second dimple 4250a protruding into the first receiving slot 101. The third elastic arm portion 4251 includes a third contact elastic arm 4251a extending toward the second intermediate portion 4250, and a third relief groove 4251b corresponding to the third contact elastic arm 4251a and providing a deformation space for the third contact elastic arm 4251a. The fourth elastic arm portion 4252 includes a fourth contact elastic arm 4252a extending toward the second intermediate portion 4250, and a fourth relief groove 4252b corresponding to the fourth contact elastic arm 4252a and providing a deformation space for the fourth contact elastic arm 4252a. In the illustrated embodiment of the present disclosure, the third contact elastic arm 4251a and the fourth contact elastic arm 4252a are located on two sides of the second intermediate portion 4250, respectively. The third contact elastic arm 4251a and the fourth contact elastic arm 4252a are aligned along the first direction A1-A1. A free end of the third contact elastic arm 4251a and a free end of the fourth contact elastic arm 4252a are both adjacent to the second intermediate portion 4250. The third contact elastic arm 4251a, the second dimple 4250a and the fourth contact elastic arm 4252a are all in contact with the first mating connector 301. This three-point contact method is beneficial to achieve better shielding effect.

In one embodiment of the present disclosure, the third elastic arm portion 4251 includes a third frame 4251c that is surrounded by all sides. The third relief groove 4251b is a closed groove and is surrounded by the third frame 4251c. The third contact elastic arm 4251a is connected to a wall of the third frame 4251c. The other three walls of the third frame 4251c respectively surround the other three sides of the third contact elastic arm 4251a. In one embodiment of the present disclosure, by arranging the third frame 4251c surrounding the third contact elastic arm 4251a, it can provide better protection for the third contact elastic arm 4251a and prevent the third contact elastic arm 4251a from being excessively deformed.

Similarly, the fourth elastic arm portion 4252 includes a surrounding fourth frame 4252c. The fourth relief groove 4252b is a closed groove and is surrounded by the fourth frame 4252c. The fourth contact elastic arm 4252a is connected to a wall of the fourth frame 4252c. The other three walls of the fourth frame 4252c respectively surround the other three sides of the fourth contact elastic arm 4252a. In one embodiment of the present disclosure, by arranging the fourth frame 4252c surrounding the fourth contact elastic arm 4252a, it can provide better protection for the fourth contact elastic arm 4252a and prevent the fourth contact elastic arm 4252a from being excessively deformed.

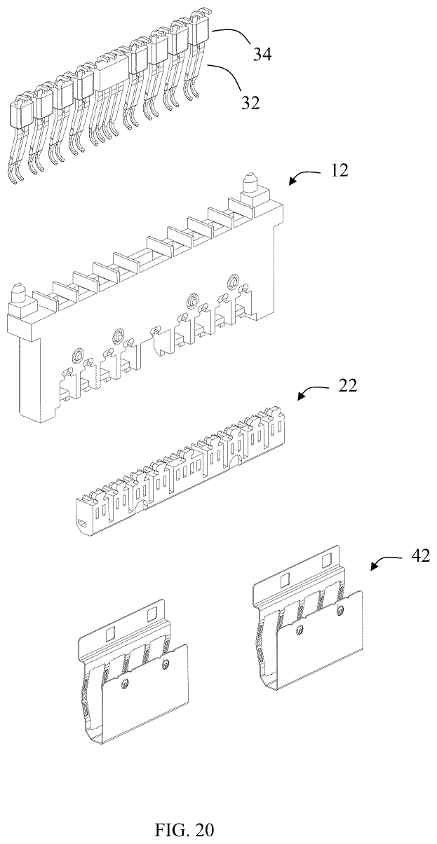

In an embodiment of the present disclosure, the second positioning posts 1224 are fixed in the second mounting positioning holes 4211, so that the third mounting plate 421 is fixed to the fourth outer surface 1222 of the second protruding portion 122. As shown in FIG. 20, a dimension of the second mounting hole 4241 along the first direction A1-A1 may be slightly larger than a dimension of the second mounting bump 1219 along the first direction A1-A1. Therefore, when the third contact elastic arm 4251a, the second intermediate portion 4250 and the fourth contact elastic arm 4252a are contacted and deformed by the first mating connector 301, the second extension plate 424 can move appropriately in the second recess 1218 along the first direction A1-A1.

When assembling the first electrical connector 100, firstly, the first insulating fixing block 21 is fixed in the first filling grooves 1123, and the second insulating fixing block 22 is fixed in the second filling grooves 1223.

Then, the first terminal modules 31a and the second terminal modules 32a are installed in the corresponding first terminal module installation slots 113 and the second terminal installation slots 123 from bottom to top along the first direction A1-A1. At this time, the first holding block 33 is fixed in the corresponding first terminal module installation slot 113, the first fixing portions 311 of the first conductive terminals 31 are disposed overhead in the corresponding first terminal module installation slot 113, in order to avoid short circuit due to contact with the first conductive housing 11. The first contact arm 310 of the first signal terminal S1 at least partially extends into the first slit 211 of the first insulating fixing block 21. The first contact arm 310 of the second signal terminal S2 at least partially extends into the second slit 212 of the first insulating fixing block 21. Similarly, the second holding block 34 is installed in the corresponding second terminal module installation slot 123, the second fixing portions 321 of the second conductive terminal 32 are disposed overhead in the second terminal module installation slot 123, in order to avoid short circuit due to contact with the second conductive housing 12. The second contact arm 320 of the third signal terminal S3 at least partially extends into the third slit 221 of the second insulating fixing block 22. The second contact arm 320 of the fourth signal terminal S4 at least partially extends into the fourth slit 222 of the second insulating fixing block 22. At this time, the first tail portion 313 of the first conductive terminal 31 is outwardly exposed in the first mounting groove 1116, and the second tail portion 323 of the second conductive terminal 32 is outwardly exposed in the second mounting groove 1216.

Then, the first ground sheet 41 and the second ground sheet 42 are installed on the first conductive housing 11 and the second conductive housing 12, respectively.

Then, the first conductive housing 11 and the second conductive housing 12 are attached to each other. The first base portion 111 corresponds to the second base portion 121. The first protruding portion 112 corresponds to the second protruding portion 122. Besides, in order to further increase the bonding force of the first conductive housing 11 and the second conductive housing 12, the first conductive housing 11 and the second conductive housing 12 are soldered or welded at the joint position. For example, as shown in FIG. 11, the first conductive housing 11 defines an upwardly recessed first welding groove 11a at the joint position, and the second conductive housing 12 defines a downwardly recessed second welding groove 12a at the joint position. The first welding groove 11a and the second welding groove 12a at corresponding positions are in communication, thereby facilitating filling of solder in the first welding groove 11a and the second welding groove 12a. As a result, the first conductive housing 11 and the second conductive housing 12 are fixed by soldering welding. When the first conductive housing 11 and the second conductive housing 12 are fixed, the first receiving slot 101 for receiving the first mating connector 301 is formed between the first protruding portion 112 and the second protruding portion 122.

Then, the first electrical connector 100 is mounted to the circuit board 400. For example, the first electrical connector 100 is fixed to the circuit board 400 by soldering or welding. The first positioning protruding post 1117 and a corresponding second positioning protruding post 1217 are assembled into a positioning post and inserted into the first positioning hole 406 of the circuit board 400. In the illustrated embodiment of the present disclosure, the first positioning protruding post 1117 and the second positioning protruding post 1217 are both half positioning protruding post. In the illustrated embodiment of the present disclosure, a cross section of the first positioning protruding post 1117 and a cross section of the second positioning protruding post 1217 are both semicircular, and jointly form a circle.

Finally, the shielding cage assembly 500 is mounted to the circuit board 400. The shielding cage assembly 500 surrounds the first electrical connector 100 and the second electrical connector 200. The first receiving cavity 500a of the shielding cage assembly 500 and the first receiving slot 101 of the first electrical connector 100 are in communication along the first direction A1-A1 to jointly receive the first mating connector 301. The second receiving cavity 500b of the shielding cage assembly 500 and the second receiving slot 101′ of the second electrical connector 200 are in communication along the first direction A1-A1 to jointly receive the second mating connector 302.

It is understandable to those skilled in the art that the order of the steps in the above assembly method can be flexibly adjusted as needed, and will not be described again in the present disclosure.

Compared with the prior art, the first electrical connector 100 of the present disclosure adopts the conductive housing 1 to replace the insulating body in the related art, thereby improving the shielding effect and improving the quality of signal transmission. Beside, by providing the first conductive housing 11 and the second conductive housing 12 separately and fixing them together, the structure is simplified. In addition, the present disclosure further provides the shielding cage assembly 500, which improves the shielding effect on the conductive terminals 3 and improves the quality of signal transmission.

It is understandable to those skilled in the art that the shielding cage assembly 500 disclosed in the illustrated embodiment of the present disclosure is different from a metal shell fixed on the insulating body in the related art. The disclosed shielding cage assembly 500 in the illustrated embodiment of the present disclosure is basically located on a periphery of the first electrical connector 100 and the second electrical connector 200, but does not emphasize the fixing function with the first electrical connector 100 and the second electrical connector 200. A space provided by the shielding cage assembly 500 for accommodating the first electrical connector 100 is greater than a space occupied by the first electrical connector 100 itself. A space provided by the shielding cage assembly 500 for accommodating the second electrical connector 200 is greater than a space occupied by the second electrical connector 200 itself. This arrangement enables the shielding cage assembly 500 to improve the shielding effect during mating.

In the description of the present disclosure, terms like “first”, “second”, “third”, “fourth” and other similar attributives are only used to name components and do not have any quantitative or logical relationship. For example, a general concept of the first conductive housing 11 and the second conductive housing 12 is the conductive housing 1; and so on.

The above embodiments are only used to illustrate the present disclosure and not to limit the technical solutions described in the present disclosure. The understanding of this specification should be based on those skilled in the art. Descriptions of directions, although they have been described in detail in the above-mentioned embodiments of the present disclosure, those skilled in the art should understand that modifications or equivalent substitutions can still be made to the application, and all technical solutions and improvements that do not depart from the spirit and scope of the application should be covered by the claims of the application.

What is claimed is:

1. A first electrical connector, configured to be mounted to a circuit board along a first direction, the first electrical connector comprising:
a conductive housing, the conductive housing defining a first receiving slot, the first receiving slot extending along the first direction and being configured to at least partially receive a first mating connector along the first direction; the first direction being perpendicular to the circuit board; and
a plurality of conductive terminals, the plurality of conductive terminals being at least partially disposed in the conductive housing. each conductive terminal comprising a contact arm, the contact arm comprising a contact portion which at least partially extends into the first receiving slot and is configured to be in electrical contact with the first mating connector; the plurality of conductive terminals being not in contact with the conductive housing.

2. The first electrical connector according to claim 1, wherein the first electrical connector comprises a first module and a second module;
the first module comprises:
a first conductive housing; and
a first terminal module, the first terminal module is at least partially disposed in the first conductive housing; the first terminal module comprises a plurality of first conductive terminals; each first conductive terminal comprises a first contact arm; the first contact arm comprises a first contact portion which at least partially extends into the first receiving slot and is configured to be in contact with the first mating connector;
the second module comprises:
a second conductive housing; and
a second terminal module, the second terminal module is at least partially disposed in the second conductive housing; the second terminal module comprises a plurality of second conductive terminals; each second conductive terminal comprises a second contact arm; the second contact arm comprises a second contact portion which at least partially extends into the first receiving slot and is configured to contact the first mating connector;
wherein the conductive housing comprises the first conductive housing and the second conductive housing; the plurality of conductive terminals comprise the plurality of first conductive terminals and the plurality of second conductive terminals; the contact arm comprises the first contact arm and the second contact arm; the contact portion comprises the first contact portion and the second contact portion.

3. The first electrical connector according to claim 2, wherein the first conductive housing of the first module and the second conductive housing of the second module are separately arranged and fixed together to jointly form the first receiving slot.

4. The first electrical connector according to claim 2, wherein the first conductive housing comprises a first positioning protruding post extending along the first direction; the second conductive housing comprises a second positioning protruding post extending along the first direction;
the circuit board defines a first positioning hole;
the first positioning protruding post and the second positioning protruding post are assembled into a positioning post which is inserted into the first positioning hole.

5. The first electrical connector according to claim 2, wherein at a joint position of the first conductive housing and the second conductive housing, the first conductive housing defines a first welding groove, and the second conductive housing defines a second welding groove communicating with the first welding groove; the first conductive housing and the second conductive housing are fixed together by soldering or welding.

6. The first electrical connector according to claim 2, wherein the first conductive housing defines a first terminal module installation slot;
the second conductive housing defines a second terminal module installation slot;
two first conductive terminals are provided in the first terminal module, the two first conductive terminals are composed of a first signal terminal and a second signal terminal; the first terminal module comprises a first holding block fixed on the first signal terminal and the second signal terminal; the first holding block is received in the first terminal module installation slot, so that the first signal terminal and the second signal terminal are disposed overhead in the first terminal module installation slot so as not to contact the first conductive housing;
two second conductive terminals are provided in the second terminal module, the two second conductive terminals are composed of a third signal terminal and a fourth signal terminal; the second terminal module comprises a second holding block fixed on the third signal terminal and the fourth signal terminal; the second holding block is received in the second terminal module installation slot, so that the third signal terminal and the fourth signal terminal are disposed overhead in the second terminal module installation slot so as not to contact the second conductive housing.

7. The first electrical connector according to claim 6, wherein the first conductive housing comprises a first filling groove;
the first module comprises a first insulating fixing block fixed in the first filling groove; the first insulating fixing block defines a first slit and a second slit which are disposed side by side;
the first contact arm of the first signal terminal extends at least partially into the first slit, and the first contact arm of the second signal terminal extends at least partially into the second slit.

8. The first electrical connector according to claim 7, wherein the second conductive housing defines a second filling groove;
the second module comprises a second insulating fixing block fixed in the second filling groove; the second insulating fixing block defines a third slit and a fourth slit which are disposed side by side;
the second contact arm of the third signal terminal at least partially extends into the third slit, and the second contact arm of the fourth signal terminal at least partially extends into the fourth slit.

9. The first electrical connector according to claim 2, wherein the first module comprises a first ground sheet; the first ground sheet comprises a first mounting plate, a second mounting plate disposed opposite to the first mounting plate, and a first connecting plate connecting one side of the first mounting plate and one side of the second mounting plate; the first mounting plate is fixed to the first conductive housing; the second mounting plate is provided with a first grounding elastic arm that protrudes into the first receiving slot and is configured to abut against the first mating connector.

10. The first electrical connector according to claim 9, wherein one end of the first grounding elastic arm is fixed, and another end of the first grounding elastic arm is movable along the first direction after the first mating connector is inserted into the first receiving slot.

11. A connector assembly, comprising:
a first electrical connector, configured to be mounted to a circuit board along a first direction, the first electrical connector comprising:
a conductive housing, the conductive housing defining a first receiving slot, the first receiving slot extending along the first direction and being configured to at least partially receive a first mating connector along the first direction; the first direction being perpendicular to the circuit board; and
a plurality of conductive terminals, the plurality of conductive terminals being at least partially disposed in the conductive housing. each conductive terminal comprising a contact arm, the contact arm comprising a contact portion which at least partially extends into the first receiving slot and is configured to be in electrical contact with the first mating connector; the plurality of conductive terminals being not in contact with the conductive housing; and
a shielding cage assembly, the shielding cage assembly being configured to be mounted to the circuit board along the first direction; the shielding cage assembly defining a first receiving cavity communicating with the first receiving slot along the first direction; the first receiving cavity and the first receiving slot being configured to jointly at least partially receive the first mating connector.

12. The connector assembly according to claim 11, wherein the shielding cage assembly comprises a first metal shell; the first metal shell comprises a first end wall and a plurality of first fixing feet protruding from the first end wall along the first direction;
the circuit board defines a plurality of first mounting holes into which the plurality of first fixing feet are pressed.

13. The connector assembly according to claim 11, wherein the shielding cage assembly comprises a first metal shell; the first metal shell comprises a first end wall which defines a first opening communicating with the first receiving cavity;
the shielding cage assembly comprises a first heat sink fixed on the first end wall; the first heat sink comprises a first body portion and a plurality of first heat dissipation fins protruding sidewardly from the first body portion; the first body portion at least partially passes through the first opening to protrude into the first receiving cavity; the first body portion is configured to contact the first mating connector.

14. The connector assembly according to claim 13, wherein the circuit board comprises a first surface, a second surface disposed opposite the first surface, and a first heat dissipation slot extending through the first surface and the second surface along the first direction; the first heat dissipation fins correspond to the first heat dissipation slot and are located above the first heat dissipation slot.

15. A connector assembly, comprising:
a first electrical connector, configured to be mounted to a circuit board along a first direction, the first electrical connector comprising:
a conductive housing, the conductive housing defining a first receiving slot, the first receiving slot extending along the first direction and being configured to at least partially receive a first mating connector along the first direction; the first direction being perpendicular to the circuit board; and
a plurality of conductive terminals, the plurality of conductive terminals being at least partially disposed in the conductive housing. each conductive terminal comprising a contact arm, the contact arm comprising a contact portion which at least partially extends into the first receiving slot and is configured to be in electrical contact with the first mating connector; the plurality of conductive terminals being not in contact with the conductive housing;
a second electrical connector, the second electrical connector defining a second receiving slot extending along the first direction; and
a shielding cage assembly, the shielding cage assembly being configured to be mounted to the circuit board, the shielding cage assembly comprising a first metal shell, a second metal shell buckled together with the first metal shell, and an intermediate metal shell fixed to the first metal shell; the intermediate metal shell dividing the shielding cage assembly into a first receiving cavity and a second receiving cavity which are disposed on two sides of the intermediate metal shell, respectively;
wherein the first receiving cavity and the first receiving slot are in communication along the first direction and are configured to jointly at least partially receive a first mating connector; and
wherein the second receiving cavity is in communication with the second receiving slot along the first direction; the second receiving cavity and the second receiving slot are configured to jointly at least partially receive a second mating connector.

16. The connector assembly according to claim 15, wherein the first electrical connector and the second electrical connector have a same structure but different installation angles.

17. The connector assembly according to claim 15, wherein the first metal shell comprises a first end wall, a first side wall bent from one end of the first end wall, and a second side wall bent from another end of the first end wall; the first end wall defines a first opening communicating with the first receiving cavity;
the second metal shell comprises a second end wall, a first retaining wall bent from one end of the second end wall, and a second retaining wall bent from another end of the second end wall; the second end wall defines a second opening communicating with the second receiving cavity;
the first retaining wall is buckled and fixed to the first side wall; the second retaining wall is buckled and fixed to the second side wall;
the shielding cage assembly comprises a first heat sink fixed on the first end wall and a second heat sink fixed on the second end wall;
the first heat sink comprises a first body portion and a plurality of first heat dissipation fins protruding sidewardly from the first body portion; the first body portion at least partially passes through the first opening to protrude into the first receiving cavity; the first body portion is configured to contact the first mating connector;
the second heat sink comprises a second body portion and a plurality of second heat dissipation fins protruding sidewardly from the second body portion; the second body portion at least partially passes through the second opening to protrude into the second receiving cavity; the second body portion is configured to contact the second mating connector.

18. The connector assembly according to claim 17, wherein the circuit board comprises a first surface, a second surface disposed opposite to the first surface, a first heat dissipation slot extending through the first surface and the second surface along the first direction, and a second heat dissipation slot extending through the first surface and the second surface along the first direction;
the first heat dissipation fins correspond to the first heat dissipation slot and are located above the first heat dissipation slot;
the second heat dissipation fins correspond to the second heat dissipation slot and are located above the second heat dissipation slot.

19. The connector assembly according to claim 17, wherein the first electrical connector comprises a first module and a second module;
the first module comprises:
a first conductive housing; and
a first terminal module, the first terminal module is at least partially disposed in the first conductive housing; the first terminal module comprises a plurality of first conductive terminals; each first conductive terminal comprises a first contact arm; the first contact arm comprises a first contact portion which at least partially extends into the first receiving slot and is configured to be in contact with the first mating connector;
the second module comprises:
a second conductive housing; and
a second terminal module, the second terminal module is at least partially disposed in the second conductive housing; the second terminal module comprises a plurality of second conductive terminals; each second conductive terminal comprises a second contact arm; the second contact arm comprises a second contact portion which at least partially extends into the first receiving slot and is configured to contact the first mating connector;
wherein the conductive housing comprises the first conductive housing and the second conductive housing; the plurality of conductive terminals comprise the plurality of first conductive terminals and the plurality of second conductive terminals; the contact arm comprises the first contact arm and the second contact arm; the contact portion comprises the first contact portion and the second contact portion.

20. The connector assembly according to claim 19, wherein the first conductive housing of the first module and the second conductive housing of the second module are separately arranged and fixed together to jointly form the first receiving slot.
